(19) United States
(12) Patent Application Publication
(10) Pub. No.: US 2024/0363801 A1
(43) Pub. Date: Oct. 31, 2024

(54) LIGHT EMITTING ELEMENT

(71) Applicant: TOYODA GOSEI CO., LTD., Kiyosu-shi (JP)

(72) Inventor: Koichi GOSHONOO, Kiyosu-shi (JP)

(21) Appl. No.: 18/632,484

(22) Filed: Apr. 11, 2024

(30) Foreign Application Priority Data
Apr. 25, 2023 (JP) 2023-071800

(51) Int. Cl. H01L 33/24; H01L 33/32; H01L 33/44; H01L 33/58

(52) U.S. Cl. CPC H01L 33/24; H01L 33/32; H01L 33/44; H01L 33/58

(57) ABSTRACT

A light emitting element, that is a flip-chip monolithic micro LED, includes a semiconductor layer including: an n-layer; an active layer located over the n-layer; and a p-layer located over the active layer, in which pixels are two-dimensionally arranged with a partial region of the semiconductor layer as one pixel, and a groove having a depth reaching the n-layer and making the semiconductor layer to have a mesa shape is formed at an outer periphery of the light emitting element, and a light attenuation portion for attenuating light from the pixel is provided at an outer periphery of the light emitting element.

### CROSS-REFERENCE TO RELATED APPLICATION

This application is based on and claims priority under 35 USC 119 from Japanese Patent Application No. 2023-071800 filed on Apr. 25, 2023.

### TECHNICAL FIELD

The present invention relates to a light emitting element.

### BACKGROUND ART

In recent years, higher definition of displays has been required, and a micro LED display has attracted attention. A micro LED display is a display in which minute LEDs on an order of 1 μm to 100 μm are arranged in a matrix, and the minute LEDs are used as one sub-pixel. As the micro LED display, a structure in which a micro LED is an individual chip and a monolithic structure in which a plurality of micro LEDs are fabricated on one chip are known. JP2021-158179A describes such a monolithic micro LED.

JP2022-138095A discloses a structure in which a side surface of a ridge portion of an ultraviolet LD is reversely tapered.

### SUMMARY OF INVENTION

However, in the conventional monolithic micro LED, light emitted from an active layer is reflected to a light extraction side by a mesa side surface formed in an outer peripheral portion of an element, and is emitted to the outside from the outer peripheral portion of the element. Therefore, the outer peripheral portion of the element appears to emit strong light, and an unintended image is displayed on the display.

The present invention has been made in view of such a background, and an object of the present invention is to provide a light emitting element that is a monolithic micro LED and in which an amount of light from an outer peripheral portion of the element is reduced.

An aspect of the present invention is a light emitting element that is a flip-chip monolithic micro LED, the light emitting element comprising a semiconductor layer including: an n-layer; an active layer located over the n-layer; and a p-layer located over the active layer, in which pixels are two-dimensionally arranged with a partial region of the semiconductor layer as one pixel, wherein a groove having a depth reaching the n-layer and making the semiconductor layer to have a mesa shape is formed at an outer periphery of the light emitting element, and a light attenuation portion for attenuating light from the pixel is provided at an outer periphery of the light emitting element.

According to the above aspect, the amount of light directed toward the outer peripheral portion of the element can be reduced by a light attenuation portion. Therefore, it is possible to realize the light emitting element that is a monolithic micro LED and in which the amount of light emitted to the outside from the outer peripheral portion of the element is reduced.

### BRIEF DESCRIPTION OF DRAWINGS

FIG. 1 is a cross-sectional view showing a configuration of a light emitting element according to a first embodiment, and is a view showing a cross section perpendicular to a main surface of a substrate.

FIG. 2 is a plan view of the light emitting element according to the first embodiment as viewed from an electrode side.

FIGS. 3A and 3B are views showing examples of a planar pattern of sub-pixels.

FIG. 4 is a diagram showing a manufacturing process of the light emitting element according to the first embodiment.

FIG. 5 is a diagram showing the manufacturing process of the light emitting element according to the first embodiment.

FIG. 6 is a diagram showing the manufacturing process of the light emitting element according to the first embodiment.

FIG. 7 is a diagram showing the manufacturing process of the light emitting element according to the first embodiment.

FIG. 8 is a diagram showing the manufacturing process of the light emitting element according to the first embodiment.

FIG. 9 is a cross-sectional view showing a configuration of a light emitting element according to a second embodiment, and is a view showing a cross section perpendicular to a main surface of a substrate.

FIG. 10 is a cross-sectional view showing a configuration of a light emitting element according to a third embodiment, and is a view showing a cross section perpendicular to a main surface of a substrate.

### DETAILED DESCRIPTION OF THE INVENTION

A light emitting element is a flip-chip monolithic micro LED that has a semiconductor layer including an n-layer, an active layer located on the n-layer, and a p-layer located on the active layer and in which pixels are two-dimensionally arranged with a partial region of the semiconductor layer as one pixel. A groove having a depth reaching the n-layer and making the semiconductor layer have a mesa shape is formed on an outer periphery of the light emitting element, and a light attenuation portion for attenuating light from the pixel is provided on an outer periphery of the light emitting element.

The light attenuation portion may be a region of the semiconductor layer in which a distance from the pixel at an outermost periphery to an upper end of the groove is equal to or larger than a width of one pixel.

The light attenuation portion may be a region of the semiconductor layer in which an angle of a side surface of the groove is 70° or more with respect to a main surface of the semiconductor layer.

The light attenuation portion may be a region of the semiconductor layer in which an angle of a side surface of the groove is larger than 90° with respect to a main surface of the semiconductor layer.

The light attenuation portion may include a light shielding portion that prevents transmission of light from the pixel on a side surface of the groove.

The light shielding portion may be made of metal. The light shielding portion may be a multilayer film in which metal and a transparent conductive film are alternately stacked.

The light shielding portion may be an n-electrode.

The light shielding portion may be provided continuously from a side surface to an upper surface of the groove.

### First Embodiment

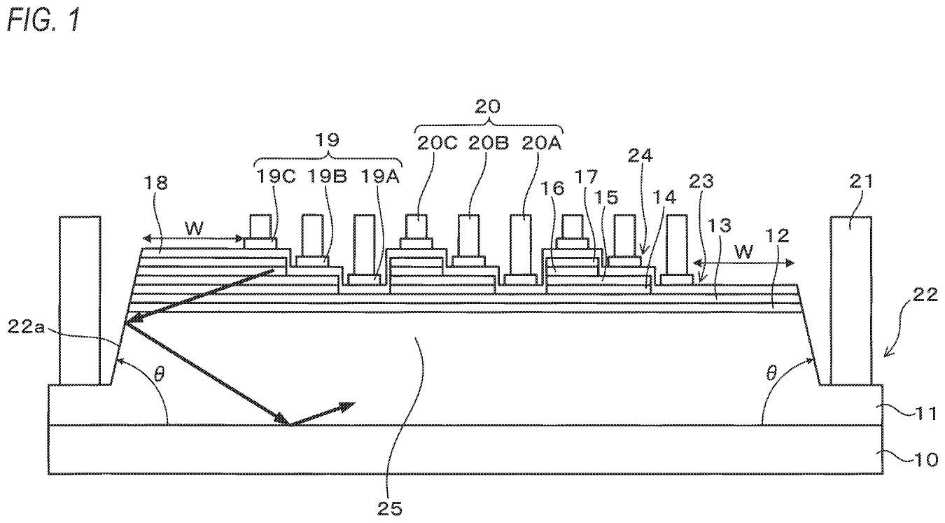

FIG. 1 is a cross-sectional view showing a configuration of a light emitting element according to a first embodiment, and is a view showing a cross section perpendicular to a main surface of a substrate. As shown in FIG. 1, the light emitting element according to the first embodiment includes a substrate 10, an n-layer 11, a first active layer 12, a first intermediate layer 13, a second active layer 14, a second intermediate layer 15, a third active layer 16, a protective layer 17, a p-layer 18, p-contact electrodes 19, p-electrodes 20, and an n-electrode 21.

The light emitting element according to the first embodiment is a flip-chip monolithic micro LED. The light emitting element is a one-chip element in which light emitting element structures emitting red, green, and blue light are two-dimensionally arranged, and is a flip-chip type. The monolithic micro LED is used as a display. Each light emitting element structure is a sub-pixel of a display, and light emitting element structures of red, green, and blue light emission are integrated to form one pixel, and the pixels are arranged in a grid pattern to form a screen.

### 1. Configuration of Light Emitting Element

The substrate 10 is a growth substrate on which a Group III nitride semiconductor is grown. A material of the substrate 10 is sapphire, Si, GaN, ScAlMgO₄, or the like.

The n-layer 11 is located on the substrate 10. The n-layer 11 is an n-type group III nitride semiconductor. Examples thereof include n-GaN, n-AlGaN, and n-InGaN. A concentration of Si is, for example, 1×10¹⁸ cm⁻³ to 100×10¹⁸ cm⁻³.

The first active layer 12 is located on the n-layer 11. The first active layer 12 is a light emitting layer of SQW or MQW structure. An emission wavelength is blue, and is 440 nm to 480 nm. The first active layer 12 has a structure in which one to nine pairs of barrier layers made of AlGaN and well layers made of InGaN are alternately stacked. The number of pairs is more preferably 1 to 7, and further preferably 1 to 5.

An ESD layer or a base layer may be provided between the n-layer 11 and the first active layer 12 as necessary. The ESD layer is a layer provided to improve an electrostatic withstand voltage. For example, GaN, InGaN or AlGaN undoped or lightly doped with Si is used.

The base layer is a semiconductor layer having a superlattice structure, and is a layer for alleviating lattice strain of the semiconductor layer. For example, group III nitride semiconductor thin films (for example, two of GaN, InGaN, and AlGaN) having different compositions are alternately stacked, and the number of pairs is, for example, 3 to 30. The base layer may be undoped, or may be doped with Si at about 1×10¹⁷ cm⁻³ to 100×10¹⁷ cm⁻³. In addition, a superlattice structure may not be used as long as the strain can be alleviated. Any material may be used as long as it has a small difference in lattice constant at a heterointerface with the first active layer 12, and may be, for example, an InGaN-layer, an AlInN-layer, or an AlGaInN-layer.

The first intermediate layer 13 is located on the first active layer 12. The first intermediate layer 13 is provided to enable light emission from the first active layer 12 and light emission from the second active layer 14 to be individually controlled. In addition, the first intermediate layer 13 also serves to protect the first active layer 12 from etching damage when a groove 23 to be described later is formed.

A material of the first intermediate layer 13 is GaN or InGaN. The first intermediate layer 13 may be non-doped or n-type. A plurality of layers having different In compositions may be used, or two layers of a non-doped layer and an n-layer may be used.

The second active layer 14 is located on the first intermediate layer 13. The second active layer 14 is a light emitting layer of SQW or MQW structure. An emission wavelength is green and is 520 nm to 550 nm. The second active layer 14 has a structure in which one to seven pairs of barrier layers made of AlGaN and well layers made of InGaN are alternately stacked. The number of pairs is more preferably 1 to 5, and further preferably 1 to 3. The number of pairs is preferably equal to or less than that of the first active layer 12, and more preferably less than that of the first active layer 12.

The second intermediate layer 15 is located on the second active layer 14. The second intermediate layer 15 is provided for the same reason as that of the first intermediate layer 13, and is provided to enable light emission from the second active layer 14 and light emission from the third active layer 16 to be individually controlled. In addition, the second intermediate layer 15 also serves to protect the second active layer 14 from etching damage when a groove 24 to be described later is formed. A material of the second intermediate layer 15 is similar to that of the first intermediate layer 13, and may be the same material.

The third active layer 16 is located on the second intermediate layer 15. The third active layer 16 is a light emitting layer of SQW or MQW structure. An emission wavelength is red and is 600 nm to 630 nm. The third active layer 16 has a structure in which one to seven pairs of barrier layers made of AlGaN and well layers made of InGaN are alternately stacked. The number of pairs is more preferably 1 to 5, and further preferably 1 to 3. The number of pairs is preferably equal to or less than that of the second active layer 14, and more preferably less than that of the second active layer 14.

The protective layer 17 is located on the third active layer 16. The protective layer 17 protects the active layer and also functions as an electron blocking layer. The protective layer 17 may be made of a material having a band gap wider than that of the well layer of the third active layer 16, such as AlGaN, GaN, or InGaN. A thickness of the protective layer 17 is preferably 2.5 nm to 50 nm, more preferably 5 nm to 25 nm. The protective layer 17 may be doped with impurities or Mg. In this case, a concentration of Mg is preferably 1×10¹⁸ cm⁻³ to 1000×10¹⁸ cm⁻³.

A partial region of the protective layer 17 is etched, and a groove 22 reaching the n-layer 11 from the protective layer 17, the groove 23 reaching the first intermediate layer 13 from the protective layer 17, and the groove 24 reaching the second intermediate layer 15 from the protective layer 17 are provided. Planar patterns of the grooves 22 to 24 will be described later.

The p-layer 18 is continuously provided on the protective layer 17, a surface of the second intermediate layer 15 exposed in the groove 24, and a surface of the first intermediate layer 13 exposed in the groove 23. The p-layer 18 is p-GaN or p-InGaN. A concentration of Mg is, for example, 1×10¹⁹ cm⁻³ to 1×10²¹ cm⁻³. The p-layer 18 may include a plurality of layers having different In compositions or concentrations of Mg.

An electron blocking layer may be provided between the p-layer 18 and the protective layer 17, between the p-layer 18 and the second intermediate layer 15 exposed in the groove 24, and between the p-layer 18 and the first intermediate layer 13 exposed in the groove 23. The electron blocking layer is a layer that blocks electrons injected from the n-layer 11 to be efficiently confined in the first active layer 12, the second active layer 14, and the third active layer 16. The electron blocking layer may be a single layer of GaN or AlGaN, a structure in which two or more of AlGaN, GaN, and InGaN are stacked, or a structure in which they are stacked with only a composition ratio changed. Alternatively, a superlattice structure may be employed. A thickness of the electron blocking layer is preferably 5 nm to 50 nm, more preferably 5 nm to 25 nm. A concentration of Mg of the electron blocking layer is preferably 1×10¹⁹ cm⁻³ to 100×10¹⁹ cm⁻³.

The p-contact electrode 19 is separately provided on the p-layer 18 in a region facing the protective layer 17, a region facing the second intermediate layer 15 exposed in the groove 24, and a region facing the first intermediate layer 13 exposed in the groove 23. A material of the p-contact electrode 19 is a material having a low contact resistance with respect to the p-layer 18, and examples thereof include Ag, Ni/Au, Co/Au, ITO/Ni/Al, Rh, Ru, ITO, and IZO. Hereinafter, in the p-contact electrode 19, a portion provided in the region facing the first intermediate layer 13 exposed in the groove 23 is referred to as a p-contact electrode 19A, a portion provided in the region facing the second intermediate layer 15 exposed in the groove 24 is referred to as a p-contact electrode 19B, and a portion provided in the region facing the protective layer 17 is referred to as a p-contact electrode 19C.

In the light emitting element according to the first embodiment, a region of the first active layer 12 facing the p-contact electrode 19A emits blue light, a region of the second active layer 14 facing the p-contact electrode 19B emits green light, and a region of the third active layer 16 facing the p-contact electrode 19C emits red light. Accordingly, the planar patterns of the p-contact electrodes 19A to 19C becomes a planar pattern of the sub-pixel.

The p-electrodes 20 are located separately on the p-contact electrodes 19A to 19C. Hereinafter, a portion provided on the p-contact electrode 19A is referred to as a p-electrode 20A, a portion provided on the p-contact electrode 19B is referred to as a p-electrode 20B, and a portion provided on the p-contact electrode 19C is referred to as a p-electrode 20C. A material of the p-electrode 20 is, for example, Ti/Au, and can be the same material as n-electrode 21.

The n-electrode 21 is located on the n-layer 11 exposed by the groove 22. A material of the n-electrode 21 is, for example, Ti/Au.

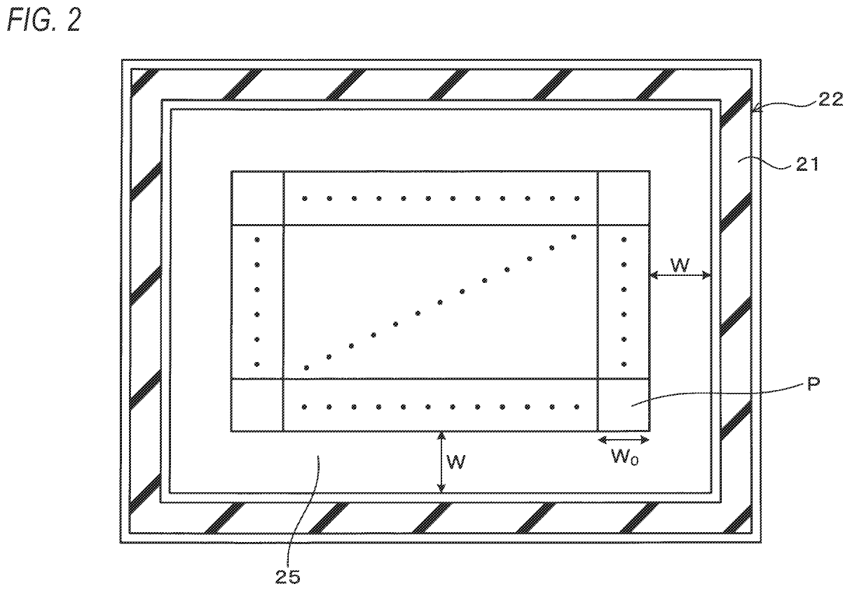

FIG. 2 is a plan view of the light emitting element according to the first embodiment as viewed from an electrode side. As shown in FIG. 2, the light emitting element has a rectangular shape in a plan view, and the groove 22 having a pattern of a rectangular ring shape is formed in an outer peripheral portion thereof. As shown in FIG. 1, due to the groove 22, the semiconductor layer (stacked layers from the n-layer 11 to the protective layer 17) has a mesa shape. The n-electrode 21 having a pattern of a rectangular ring shaped is provided inside the groove 22 in a plan view.

Pixels P are arranged in a square lattice shape inside the groove 22. The pixel P is a square, and a length W0 of one side thereof is a width of the pixel P. The pixel P may be rectangular, in which case a length of a short side is the width W0 of the pixel.

As shown in FIGS. 1 and 2, a light attenuation portion 25 is provided between the pixel P at an outermost periphery and the groove 22. The light attenuation portion 25 has a region (a first light attenuation portion) having a width W from an end surface of the pixel P at the outermost periphery on the groove 22 side to an upper end of the groove 22 (a corner portion formed by an upper surface of the groove 22 and a side surface 22a), and a region (a second light attenuation portion, not shown in FIG. 2) of the side surface 22a of the groove 22. The first light attenuation portion is a region of a semiconductor layer in which the p-electrode 20 is not provided and which does not emit light. The width W is larger than or equal to the width W0 of the pixel P.

As shown in FIG. 1, the first light attenuation portion of the light attenuation portion 25 may be a region where no groove is provided (a region where uppermost surface is the protective layer 17), or may be a region where the groove 23 or the groove 24 is provided (a region where the first intermediate layer 13 or the second intermediate layer 15 is exposed). In order to further enhance a light attenuation effect by the light attenuation portion 25, the first light attenuation portion is preferably the region where the uppermost surface is the protective layer 17.

The amount of light on the side surface 22a of the groove 22 is inversely proportional to the square of a distance from the first active layer 12, the second active layer 14, and the third active layer 16 to the side surface 22a. In the first embodiment, the distance to the side surface 22a is increased by providing the first light attenuation portion of the light attenuation portion 25. This can sufficiently reduce the amount of light reaching the side surface 22a. As a result, it is possible to reduce the amount of light transmitted through the side surface 22a or reflected by the side surface 22a and emitted to the outside from the outer peripheral portion of the element.

The width W of the light attenuation portion 25 is preferably 1.5 times or more the width W0 of one pixel. More preferably, the width W of the light attenuation portion 25 is three times or more the width W0 of one pixel. The amount of light emitted from the outer peripheral portion of the element to the outside can be further reduced. In addition, the width W of the light attenuation portion 25 is preferably 10 times or less the width W0 of one pixel. This is because if the width W0 is too large, a region that does not emit light increases, and an element area increases.

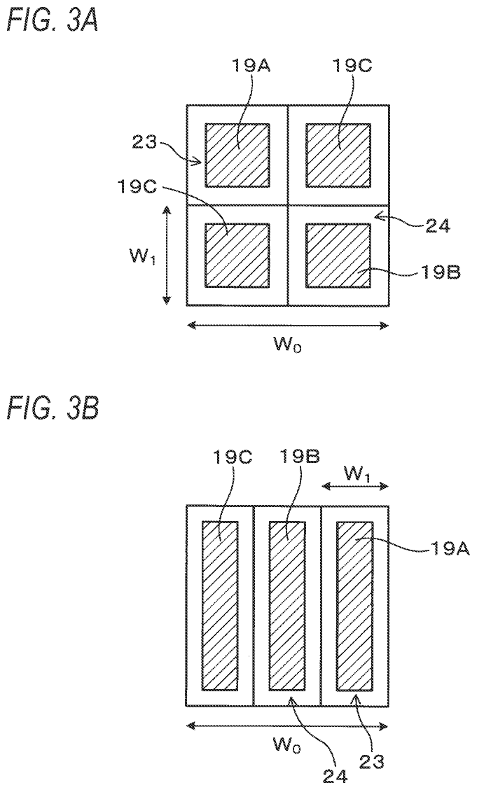

FIGS. 3A and 3B are views showing examples of a planar pattern of the sub-pixels. In FIG. 3A, four square sub-pixels are arranged in 2×2 to form one pixel P. Of the 2×2 sub-pixels, two diagonal sub-pixels are red sub-pixels, and the other two sub-pixels are green and blue sub-pixels. Normally, since red light emission is weaker than blue and green light, the number of red sub-pixels is increased by one.

In FIG. 3B, the sub-pixels are formed in a rectangular shape, and three sub-pixels are arranged in a stripe shape to form one pixel P. The three sub-pixels are blue, green, and red sub-pixels, respectively. In FIG. 3B, the lengths of the short sides of the respective sub-pixels are made uniform, but the lengths may be changed depending on the color. For example, the length of the short sides of red may be longer than that of green or blue.

Of course, the pattern of the sub-pixels is not limited thereto, and various conventionally known patterns can be adopted.

When the sub-pixel is square as shown in FIG. 3A, the length of one side is a width W1 of the sub-pixel, and when the sub-pixel is rectangular as shown in FIG. 3B, the length of the short side is the width W1 of the sub-pixel. When W1 is different among the sub-pixels of the respective colors, the largest value is set to W1. In addition, when the sub-pixel has a shape other than a square or a rectangle, a diameter of a circumscribed circle is set to W1.

In this case, the width W of the light attenuation portion 25 is preferably three times or more the width W1 of the sub-pixel. Since the amount of light is attenuated in inverse proportion to the square of the distance, when the width W is three times the width W1, the amount of light can be reduced to about 1/10 of that in a case where the width W is one time the width W1. Therefore, the amount of light emitted from the outer peripheral portion of the element to the outside can be sufficiently reduced. More preferably, the width W is five times or more the width W1 of the sub-pixel.

In the second light attenuation portion of the light attenuation portion 25, an angle θ of the side surface 22a (an angle with respect to a main surface of the substrate 10) is preferably 70° or more. Here, θ defines a rotation direction as shown in FIG. 1. By setting the angle θ of the side surface 22a of the groove 22 to 70° or more, the light directed toward the light extraction side, of the light reflected by the side surface 22a, is reduced. In addition, of the light reflected by the side surface 22a, a proportion of light whose propagation direction is at a shallow angle with respect to the main surface of the substrate 10 increases, a proportion of light that is totally reflected at an interface between the substrate 10 and the n-layer 11 increases, and therefore, the amount of light emitted to the outside from the light extraction side is reduced. As a result, the amount of light emitted from the outer peripheral portion of the element to the outside can be reduced.

The angle θ of the side surface 22a of the groove 22 is more preferably an angle (an angle larger than 90°) at which the groove 22 is reversely tapered. That is, it is preferable that the inclination is such that a cross-sectional area of the element in a plane parallel to the main surface of the substrate 10 increases as a distance from the substrate 10 increases. When the side surface 22a is reversely tapered, the proportion of the light directed toward the light extraction side, of the light reflected by the side surface 22a, decreases, and a large amount of light is not extracted to the outside due to total reflection at the interface between the substrate 10 and the n-layer 11 even when the light is directed toward the light extraction side. As a result, the light extracted to the outside from the outer peripheral portion of the element can be further reduced. More preferably, the angle θ of the side surface 22a is 1000 or more.

An upper limit of the angle θ of the side surface 22a is not particularly limited, but the angle of the side surface 22a is preferably 1350 or less from a viewpoint of ease of manufacturing. The angle is more preferably 120° or less.

A light shielding member that shields light from the light emitting element according to the first embodiment may be disposed on an outer peripheral portion on a back surface of the substrate 10. In addition, a similar light shielding member may be disposed in an optical member in a subsequent stage. This can further reduce the light in the outer peripheral portion of the element. At this time, since the first light attenuation portion of the light attenuation portion 25 has the width W, a certain degree of error in arrangement of the light shielding member is allowed, and positioning of the light shielding member is facilitated.

As described above, in the light emitting element in the first embodiment, since the light attenuation portion 25 is provided at the outer peripheral portion of the element, it is possible to reduce light emission from the outer peripheral portion of the element. Therefore, the outer peripheral portion of the element does not appear to emit light, and an intended image can be displayed.

### 2. Manufacturing Method for Light Emitting Element

A manufacturing method for the light emitting element according to the first embodiment will be described with reference to the drawings.

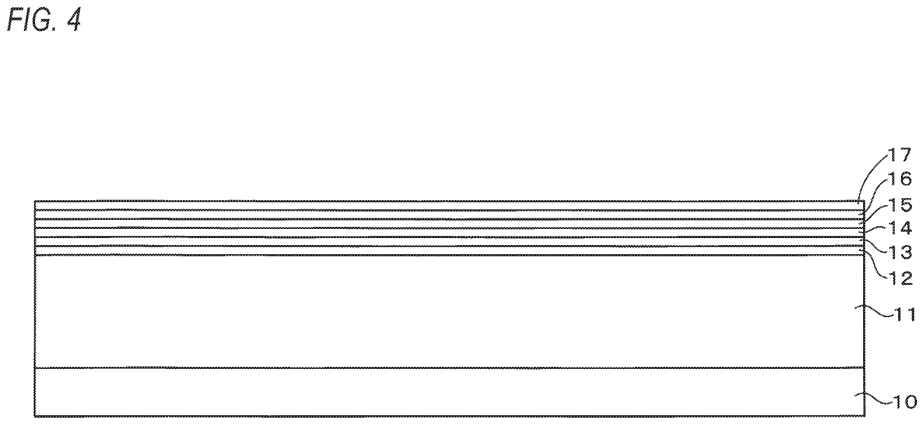

First, as shown in FIG. 4, the n-layer 11, the first active layer 12, the first intermediate layer 13, the second active layer 14, the second intermediate layer 15, the third active layer 16, and the protective layer 17 are stacked on the substrate 10 in this order from the substrate 10 side by MOCVD.

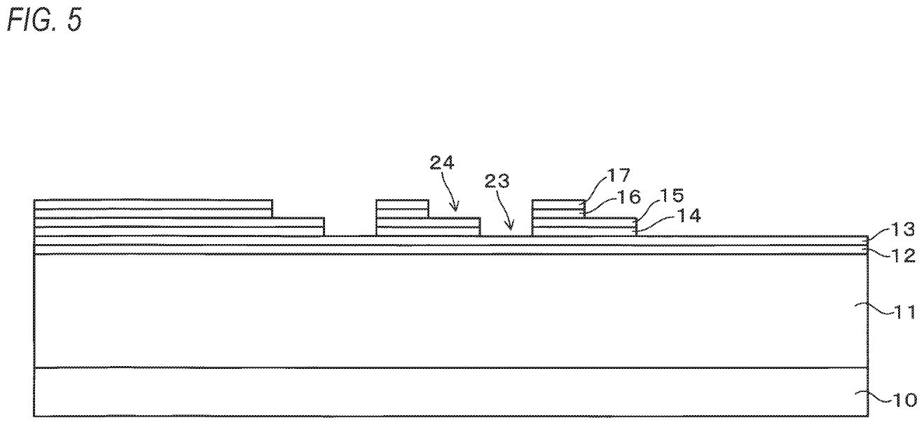

Next, as shown in FIG. 5, a partial region of the protective layer 17 is dry-etched to form the grooves 23 and 24. The groove 23 is etched until the first intermediate layer 13 is exposed, and the groove 24 is etched until the second intermediate layer 15 is exposed.

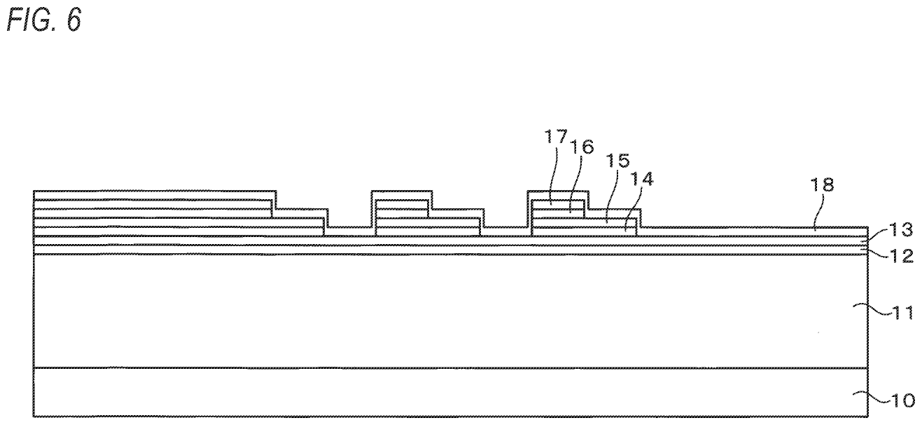

Next, as shown in FIG. 6, the p-layer 18 is formed continuously on a surface of the protective layer 17, a bottom surface of the groove 24, and a bottom surface of the groove 23 by MOCVD.

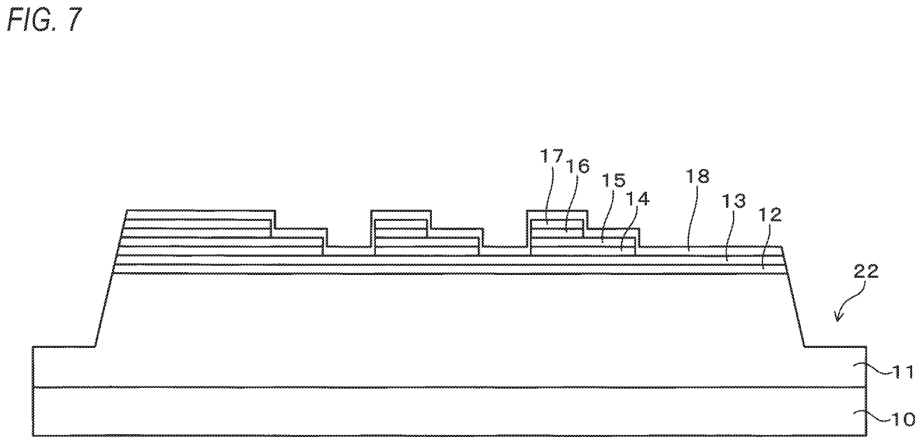

Next, as shown in FIG. 7, a predetermined region of the p-layer 18 is dry-etched to form the groove 22. The groove 22 is etched until the n-layer 11 is exposed. The groove 22 is formed so that the width W from the pixel at the outermost periphery to the upper end of the groove 22 is equal to or larger than the width W0 of the pixel. The angle of the side surface 22a of the groove 22 can be controlled by etching conditions. Then, the groove 22 may be etched so that the angle of the side surface 22a is 70° or more, preferably more than 90° (that is, the groove 22 is reversely tapered).

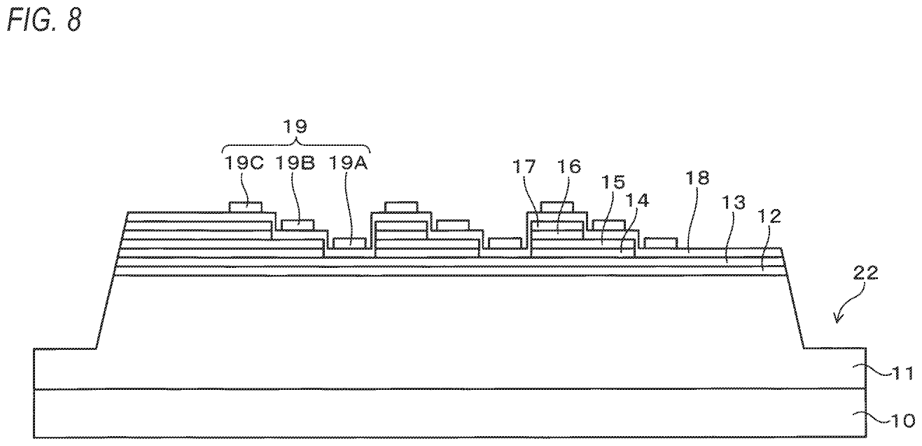

Next, as shown in FIG. 8, by sputtering or vapor deposition, the p-contact electrode 19A is formed on the p-layer 18 in a region of the groove 23, the p-contact electrode 19B is formed on the p-layer 18 in a region of the groove 24, and the p-contact electrode 19C is formed on the p-layer 18 in a region corresponding to an upper portion of the protective layer 17.

Next, by sputtering or vapor deposition, the p-electrodes 20A to 20C are formed on the p-contact electrodes 19A to 19C, and the n-electrode 21 is formed on the n-layer 11 exposed at the bottom surface of the groove 22. Since the p-electrodes 20A to 20C and the n-electrode 21 are made of the same material, the p-electrodes 20A to 20C and the n-electrode 21 can be formed simultaneously. Thus, the light emitting element according to the first embodiment shown in FIG. 1 can be manufactured.

### Second Embodiment

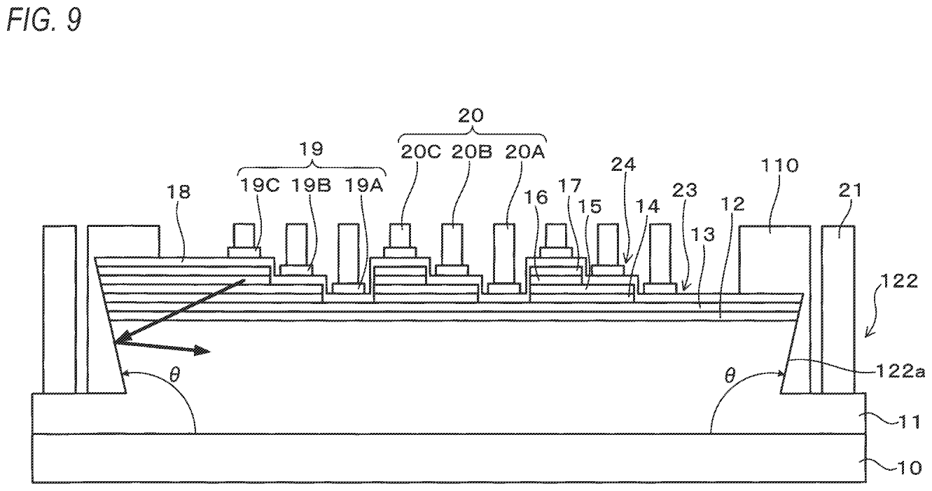

FIG. 9 is a cross-sectional view showing a configuration of a light emitting element according to a second embodiment, and is a view showing a cross section perpendicular to a main surface of a substrate. As shown in FIG. 9, the light emitting element according to the second embodiment has the same configuration as that of the first embodiment except that the light attenuation portion 25 of the light emitting element according to the first embodiment is changed as follows.

In the light emitting element according to the second embodiment, a groove 122 is provided instead of the groove 22. The difference from the groove 22 is an inclination angle of a side surface 122a of the groove 122, and the side surface 122a has a reverse taper, that is, the inclination angle is larger than 90°. The other configurations are the same as those of the groove 22.

In the light emitting element according to the second embodiment, a light shielding portion 110 is provided to cover the side surface 122a as a third light attenuation portion of the light attenuation portion 25. The light shielding portion 110 reduces an amount of light emitted from the side surface 122a to the outside and reduces reflection of light on the side surface 122a.

The light shielding portion 110 may have a configuration in which a transmittance of light from the first active layer 12, the second active layer 14, and the third active layer 16 is low. For example, the transmittance is preferably 50% or less. In addition, the light shielding portion 110 is preferably configured such that a reflectance of light from the first active layer 12, the second active layer 14, and the third active layer 16 is low. In short, it is preferable that an absorptivity of light from the first active layer 12, the second active layer 14, and the third active layer 16 is high.

For example, the light shielding portion 110 may be made of a material that absorbs light of wavelengths of red, green, and blue, such as metal. Specifically, Ti, V, Mo, W, Cr, Ni, Ta, or the like can be used. In this case, a thickness of the light shielding portion 110 is preferably 50 nm or more. The absorptivity can be sufficiently increased.

For example, a multilayer film in which metal and a transparent conductive film are alternately stacked may be used, and the thickness may be set such that reflection of light of wavelengths of red, green, and blue is weakened by interference. When such a multilayer film is used, it is possible not only to reduce reflection due to interference but also to cause absorption by metal. Ti, V, Mo, W, Cr, Ni, Ta, or the like can be used as the metal of the multilayer film. In addition, ITO, IZO, or the like can be used as the transparent conductive film. In the case of such a multilayer film, a first layer and a last layer may be made of metal or a transparent conductive film.

The light shielding portion 110 is not necessarily required to be made of a conductive material. However, when the conductive material is used, the p-layer 18 and the n-layer 11 can be electrically short-circuited on the side surface 122a of the groove 122. Therefore, when light is absorbed in the semiconductor layer, particularly in the first active layer 12, the second active layer 14, and the third active layer 16, and electrons and holes are generated, the electrons and holes can be efficiently extracted by the light shielding portion 110. Accordingly, since it is possible to prevent recombination of electrons and holes to emit light, it is possible to further reduce the amount of light emitted from the outer peripheral portion of the element to the outside. In order to more effectively extract electrons and holes, a voltage may be applied so that the p-layer 18 and the n-layer 11 are reversely biased on the side surface 122a of the groove 122.

The light shielding portion 110 may be continuously provided not only on the side surface 122a of the groove 122 but also on the bottom surface or the upper surface thereof (the protective layer 17, the bottom surface of the groove 23 or the bottom surface of the groove 24, that is, a region in the vicinity of the groove 122).

The light shielding portion 110 may be formed by sputtering or ALD. The reverse tapered side surface 122a can be covered with high accuracy. In particular, when ALD is used in the case of a multilayer film, a film thickness can be controlled with high accuracy, and therefore characteristics as designed can be realized.

As described above, according to the light emitting element according to the second embodiment, the light shielding portion 110 can prevent transmission of light from the side surface 122a of the groove 122, and can absorb a part of the light reaching the side surface 122a. Further, since the side surface 122a is reversely tapered, most of the light reflected on the side surface 122a can be reflected to a side opposite to the light extraction side. Even if the light is reflected to the light extraction side, the angle is small with respect to the main surface of the substrate 10, and therefore the light is not extracted to the outside due to total reflection. As a result, the amount of light emitted from the outer peripheral portion of the element to the outside can be reduced.

### Third Embodiment

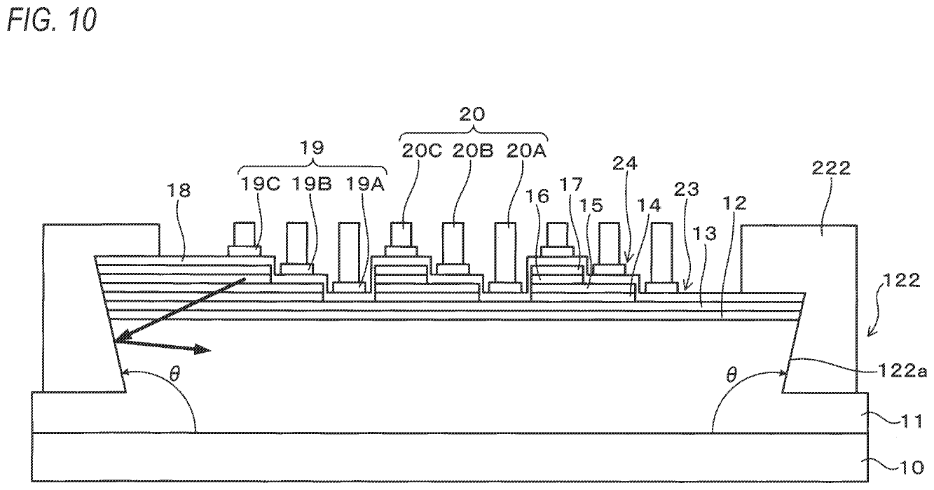

FIG. 10 is a cross-sectional view showing a configuration of a light emitting element according to a third embodiment, and is a view showing a cross section perpendicular to a main surface of a substrate. As shown in FIG. 10, in the light emitting element according to the third embodiment, an n-electrode 222 also serves as the light shielding portion 110 according to the second embodiment, and other configurations are the same as those of the second embodiment.

As shown in FIG. 10, the n-electrode 222 is provided continuously on the bottom surface of the groove 122, the side surface 122a, and the upper surface thereof. The n-electrode 222 is not necessarily required to be provided on the upper surface of the groove 122, but by providing the n-electrode 222 on the upper surface thereof, a height of the p-electrode 20 and a height of the n-electrode 21 can be aligned, and mounting of the light emitting element in the third embodiment on a mounting substrate becomes easy.

The n-electrode 222 can be made of the same material as that of the n-electrode 21 of the light emitting element in the first and second embodiments. Since the n-electrode 222 is made of a metal material, the n-electrode 222 exhibits the same function as that of the light shielding portion 110 of the light emitting element according to the second embodiment. That is, transmission of light from the side surface 122a can be prevented. In addition, it is possible to absorb a part of the light reaching the side surface 122a.

Since the side surface 122a is reversely tapered, most of the light reflected on the side surface 122a can be reflected to the side opposite to the light extraction side. Even if the light is reflected to the light extraction side, the angle is small with respect to the main surface of the substrate 10, and therefore the light is not extracted to the outside due to total reflection. As a result, the amount of light emitted from the outer peripheral portion of the element to the outside can be reduced.

The n-electrode 222 electrically short-circuits the p-layer 18 and the n-layer 11 on the side surface 122a of the groove 122. Therefore, when light is absorbed in the semiconductor layer, particularly in the first active layer 12, the second active layer 14, and the third active layer 16, and electrons and holes are generated, the electrons and holes can be efficiently extracted by the n-electrode 222. Accordingly, since it is possible to prevent the recombination of electrons and holes to emit light, it is possible to further reduce the amount of light emitted from the outer peripheral portion of the element to the outside.

Since a sufficiently long distance is secured from the n-electrode 222 to the p-electrode 20 by the light attenuation portion 25, an operation of the element is not affected even if the n-layer 11 and the p-layer 18 are electrically short-circuited at the side surface 122a by the n-electrode 222.

The n-electrode 222 may be formed by sputtering. The reverse tapered side surface 122a of the groove 122 can be accurately covered.

According to the light emitting element of the third embodiment, the structure can be made simpler than that of the light emitting element of the second embodiment. Further, since the light shielding portion 110 is not separately provided, the element area can be further reduced.

### Modification

The first to third embodiments are monolithic micro LEDs capable of performing full-color display with sub-pixels of three colors of blue, green, and red as one pixel, but the present invention is not limited thereto. A single color monolithic micro LED may be used. Further, sub-pixels of two colors or four or more colors may be set as one pixel. Alternatively, a full color may be realized by wavelength conversion using a phosphor, a quantum dot, or the like.

### REFERENCE SIGNS LIST

10: substrate
11: n-layer
12: first active layer
13: first intermediate layer
14: second active layer
15: second intermediate layer
16: third active layer
17: protective layer
18: p-layer
19, 19A to 19C: p-contact electrode
20, 20A to 20C: p-electrode
21, 222: n-electrode
22 to 24: groove
25: light attenuation portion
110: light shielding portion

What is claimed is:

1. A light emitting element that is a flip-chip monolithic micro LED, the light emitting element comprising a semiconductor layer including: an n-layer; an active layer located over the n-layer; and a p-layer located over the active layer, in which pixels are two-dimensionally arranged with a partial region of the semiconductor layer as one pixel, wherein
a groove having a depth reaching the n-layer and making the semiconductor layer to have a mesa shape is formed at an outer periphery of the light emitting element, and
a light attenuation portion for attenuating light from the pixel is provided at an outer periphery of the light emitting element.

2. The light emitting element according to claim 1, wherein
the light attenuation portion is a region of the semiconductor layer in which a distance from the pixel at an outermost periphery to an upper end of the groove is equal to or larger than a width of one of the pixels.

3. The light emitting element according to claim 1, wherein
the light attenuation portion is a region of the semiconductor layer in which a distance from the pixel at an outermost periphery to an upper end of the groove is three times or more a width of one of the pixels.

4. The light emitting element according to claim 1, wherein
the light attenuation portion is a region of the semiconductor layer in which an angle of a side surface of the groove is 70° or more with respect to a main surface of the semiconductor layer.

5. The light emitting element according to claim 2, wherein
the light attenuation portion is a region of the semiconductor layer in which an angle of a side surface of the groove is 70° or more with respect to a main surface of the semiconductor layer.

6. The light emitting element according to claim 3, wherein
the light attenuation portion is a region of the semiconductor layer in which an angle of a side surface of the groove is 70° or more with respect to a main surface of the semiconductor layer.

7. The light emitting element according to claim 4, wherein
the angle of the side surface of the groove is larger than 90° with respect to the main surface of the semiconductor layer.

8. The light emitting element according to claim 5, wherein
the angle of the side surface of the groove is larger than 90° with respect to the main surface of the semiconductor layer.

9. The light emitting element according to claim 6, wherein
the angle of the side surface of the groove is larger than 90° with respect to the main surface of the semiconductor layer.

10. The light emitting element according to claim 1, wherein
the light attenuation portion includes a light shielding portion, that prevents transmission of light from the pixels, at a side surface of the groove.

11. The light emitting element according to claim 2, wherein
the light attenuation portion includes a light shielding portion, that prevents transmission of light from the pixels, at a side surface of the groove.

12. The light emitting element according to claim 3, wherein
the light attenuation portion includes a light shielding portion, that prevents transmission of light from the pixels, at a side surface of the groove.

13. The light emitting element according to claim 10, wherein
the light shielding portion is made from metal.

14. The light emitting element according to claim 11, wherein
the light shielding portion is made from metal.

15. The light emitting element according to claim 10, wherein
the light shielding portion is a multilayer film in which metal and a transparent conductive film are alternately stacked.

16. The light emitting element according to claim 11, wherein
the light shielding portion is a multilayer film in which metal and a transparent conductive film are alternately stacked.

17. The light emitting element according to claim 10, wherein
the light shielding portion is an n-electrode.

18. The light emitting element according to claim 11, wherein
the light shielding portion is an n-electrode.

19. The light emitting element according to claim 17, wherein
the light shielding portion is provided continuously from the side surface to an upper surface of the groove.

20. The light emitting element according to claim 18, wherein
the light shielding portion is provided continuously from the side surface to an upper surface of the groove.
